(19) United States
(12) Patent Application Publication
(10) Pub. No.: US 2010/0109920 A1
(43) Pub. Date: May 6, 2010

(54) SECURITY - INPUT KEY SHUFFLE

(76) Inventor: Michael Dennis Spradling, Raleigh, NC (US)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(21) Appl. No.: 12/265,078

(22) Filed: Nov. 5, 2008

(51) Int. Cl. H03M 11/00

(52) U.S. Cl. 341/23

(57) ABSTRACT

An electronic device and method for securely entering textual input into the device. An electronic device has a keypad area and a plurality of keys disposed within the keypad area, each key having a character associated therewith and the characters being arranged on the keypad in a particular order. The electronic device includes a keypad security application for changing the characters associated with the keys. When activated, the keypad security application functions by changing the characters associated with the keys following the selection of a character by a user for input into the electronic device. The keypad security application associates at least two characters with different keys such that the arrangement or order of the characters on the keypad is changed.

### TECHNICAL FIELD OF THE INVENTION

The present invention relates to electronic equipment into which textual input may be entered and a method for maintaining privacy or security of textual input entered.

### DESCRIPTION OF THE RELATED ART

Various electronic devices have the capability of and are used to input text into the device. In some instances, the text being entered by the user is sensitive information that the user wishes to be kept secret. Examples of such information may include a password, pin number, security code, and the like. It may also include text that forms the body of a message such as e-mail or a text message. Such sensitive input may be required for various reasons such as, for example, opening a document, accessing an account such as a bank account or a user account on a website, and the like. Mobile electronic devices, e.g., mobile phones, PDA's, etc., often have Internet capabilities and wireless capabilities to connect to other devices. With such capabilities, mobile electronic devices are being used in more transactions and interactions where the input of private or sensitive text is required, e.g. money transactions, such as purchasing of goods or transfer of funds to bank accounts, opening documents, accessing internet accounts, or even to unlock a function on the device. Electronic devices that may accept textual input may include applications to provide an on-screen security feature to protect the identity of security codes such as pin numbers, passwords, etc. from other persons who may be able to view the screen when a user enters the text. In the operation of these on-screen security features, the device's screen does not display the actual character that was entered as input but, rather, displays a non-descript character for each character entered. For example, each character may be represented by an asterisk “*”, a number sign “#”, a dot “•”, or the like.

### SUMMARY

The present invention provides an electronic device having a keypad for entering at least one character as input into the device. The keypad includes a plurality of keys, and each key has a character associated therewith. The characters are associated with the keys and arranged in particular order, arrangement, or layout on the keypad. The device includes a keypad security application for changing the arrangement of the characters on the keypad after a user selects and enters a character as input into the electrical device. Changing the arrangement of the characters on the keypad after selecting a character as input provides an electronic device with another level of security for entering input into the device that may be of a private or secretive. By changing the arrangement of the characters on the keypad, persons in the vicinity of the electronic device may not be able to determine what characters the user has entered into the device simply by observing what key position the user has selected.

According to one aspect of the invention. An electronic device comprising a keypad for entry of at least one character as input into the electronic device by a user, the keypad comprising a plurality of keys, each key having a character associated therewith, the characters being arranged in a first character arrangement; and a keypad security application, the keypad security application changing the arrangement of the characters on the keypad to a second character arrangement in response to entry of a character as input into the electronic device by associating the at least two characters with different keys relative to the keys that at least two characters were associated with in the first arrangement.

In one embodiment, the electronic device is a portable network device.

In one embodiment, the first character arrangement is a pre-stored arrangement.

In one embodiment, the first character arrangement is a randomly generated arrangement of the characters.

In one embodiment, the second character arrangement is a pre-stored arrangement.

In one embodiment, the second character arrangement is a randomly generated arrangement of the characters.

In one embodiment, the keypad comprises a touch sensitive display and the keys are virtual keys displayed by the touch sensitive display.

In one embodiment, the keypad comprises a plurality of physical keys.

According to another aspect of the invention, a method for securely inputting information into an electronic device including a keypad having a plurality of keys, each key having a character associated therewith, the characters being disposed in a primary character arrangement on the keypad comprises providing a first character arrangement on the keypad; and changing the arrangement of at least two characters on the keypad following a selection of a character as input to provide a second character arrangement, the character arrangement being changed by associating at least two characters with different keys relative to the keys the at least two characters were associated with in the first arrangement.

In one embodiment of the method, the first character arrangement is the same as the primary character arrangement.

In one embodiment of the method, providing the first character arrangement comprises providing a character arrangement that is different from the primary character arrangement.

In one embodiment of the method, providing the first character arrangement comprises providing a randomly generated character arrangement.

In one embodiment of the method, providing the first character arrangement comprises providing a pre-stored character arrangement.

In one embodiment of the method, changing the arrangement of the characters on the keypad following a selection of a character as input comprises randomly generating the character arrangement.

In one embodiment of the method, changing the arrangement of the characters on the keypad following a selection of a character as input comprises providing a pre-stored character arrangement.

In one embodiment of the method, the method comprises changing the arrangement of at least two characters on the keypad in response to each selection of a character as input.

In one embodiment of the method, the method comprises changing the arrangement of at least two characters on the keypad after a pre-determined number of character input selections has been made.

In one embodiment of the method, the method comprises changing the arrangement of the characters until a pre-determined end input selection has been made.

In one embodiment of the method, the method comprises changing the character arrangement to the primary character arrangement after the entry of the pre-determined end input selection.

These and other features of the present invention will be apparent with reference to the following description and attached drawings. In the description and drawings, particular embodiments of the invention have been disclosed in detail as being indicative of some of the ways in which the principles of the invention may be employed, but it is understood that the invention is not limited correspondingly in scope. Rather, the invention includes all changes, modifications and equivalents coming within the spirit and terms of the claims appended hereto.

Features that are described or illustrated with respect to one embodiment may be used in the same way or in a similar way in one or more other embodiments and/or in combination with or instead of the features of the other embodiments.

It should be emphasized that the term “comprises/comprising” when used in the specification is taken to specify the presence of stated features, integers, steps, or components, but does not preclude the presence or addition of one or more features, integers, steps, components, or groups thereof.

### BRIEF DESCRIPTION OF THE DRAWINGS

Aspects of the invention may be better understood with reference to the following drawings. The components of the drawings are not necessarily to scale, emphasis instead being placed upon clearly illustrating the principles of the present invention. Likewise, elements and features in one drawing may be combined with elements and features depicted in other drawings. Moreover, like reference numerals designate corresponding parts throughout the several views.

While the diagrams or flow charts may show a specific order of executing functional logic blocks, the order of execution of the blocks may be changed relative to the order shown. Also, two or more blocks shown in succession may be executed concurrently or with partial concurrence. Certain blocks also may be omitted. In addition, any number of commands, state variables, semaphores, or messages may be added to the logical flow for purposes of enhanced utility, accounting, performance, measurement, troubleshooting, and the like. It is understood that all such variations are within the scope of the present invention.

FIG. 1 is a schematic illustration of an electronic device, e.g., in the form of a portable communication device;

FIG. 2 is a schematic illustration of components of an exemplary mobile device in accordance with aspects of the present invention;

FIG. 3 is a schematic flow chart illustrating an exemplary logic or processing flow which the keypad security application may operate;

FIG. 4 is a close-up view of the keypad and a character arrangement for the keys of the portable communication device of FIG. 1; and

FIGS. 5-8 are schematic illustrations of a user operating a keypad and changes of character arrangement in accordance with the logic flow chart of FIG. 3.

### DETAILED DESCRIPTION OF EMBODIMENTS

The term “electronic equipment” and “electronic device,” which are used interchangeably, include portable radio communication equipment. The term “portable radio communication equipment,” which herein after is referred to as a “mobile radio terminal,” includes all equipment such as mobile telephones, pagers, communicators, i.e., electronic organizers, personal digital assistants (PDAs), smartphones, portable communication apparatus or the like. The term “portable communication device” includes any portable electronic equipment including, for example, mobile radio terminals, mobile telephones, mobile devices, mobile terminals, communicators, pagers, electronic organizers, personal digital assistants, smartphones and the like. The term “portable communication device” also may include portable digital music players and/or video display devices, e.g., iPod devices, MP3 players, DVD players, etc.

In the present application, aspects of the invention are described primarily in the context of a mobile telephone. However, it will be appreciated that the invention is not intended to be limited to a mobile telephone and can be any type of electronic equipment that may be used to enter or input text including a computer. Electronic equipment may also include, for example, a transaction terminal. Electronic equipment may also include, for example, an ATM machine, a credit card reader at a merchant's point-of-sale terminal, and the like. In general, aspects of the present invention relate to an electronic device, method, and computer program for securely entering text or other desired input into electronic equipment.

The use of ordinal numbers (e.g., “first,” “second,” “third,” “fourth,” etc.) before a term is used (unless expressly specified otherwise) for purposes of convenience to distinguish one feature or component from another feature or component that is described by the same or a similar term. Further, the use of ordinal numbers such as “first” and “second” before a term does not indicate that there must be no more than two insistences of that term.

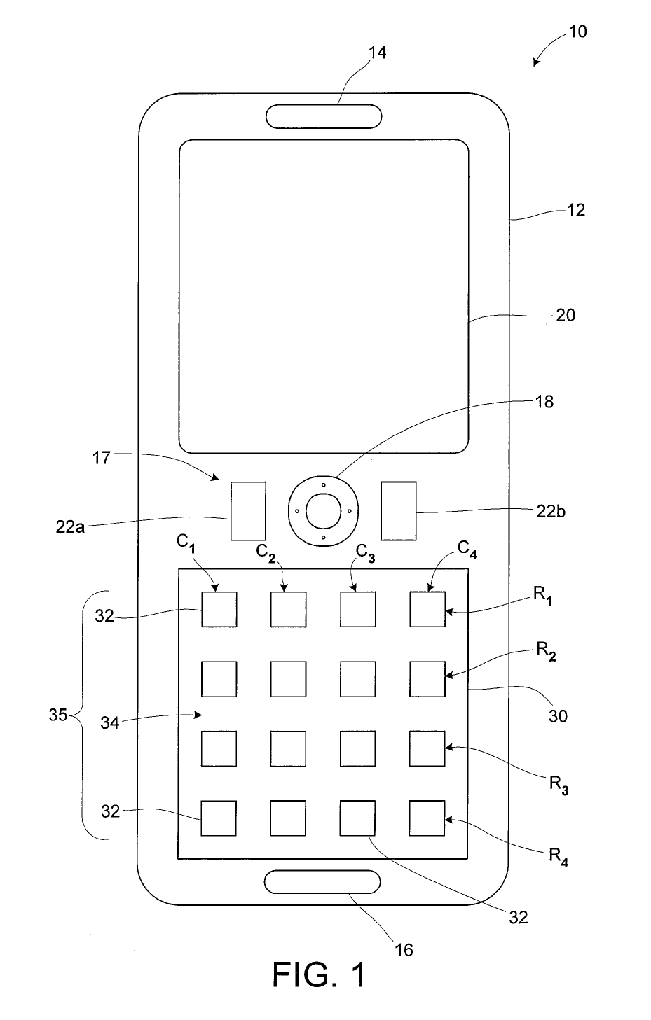

Referring to FIG. 1, an electronic device 10 is shown in accordance with the present invention. The electronic device 10 in the exemplary embodiment is a mobile telephone, and will be referred to as the mobile telephone 10. The mobile telephone 10 is shown as having a “brick” or “block” design type housing 12, but it will be appreciated that other type housings, such as clamshell housing or a slide-type housing, may be utilized without departing from the scope of the invention.

As illustrated in FIG. 1, the mobile telephone 10 may include a user interface that enables the user to easily and efficiently perform one or more communication tasks (e.g., enter in text, display text or images, send an E-mail, display an E-mail, receive an E-mail, identify a contact, select a contact, make a telephone call, receive a telephone call, etc). The mobile phone 10 includes case (housing) 12, speaker 14, microphone 16, a number of keys 17, and display 20, e.g., liquid crystal display, light emitting diode display, or other display. The keys 17 may include a number of keys having different respective functions. For example, the key 18 may be a navigation key, selection key, or some other type of key, and the keys 22a, 22b may be, for example, soft keys or soft switches. As an example, the navigation key 18 may be used to scroll through lists shown on the display 20, to select one or more items shown in a list on the display 20, etc. The soft switches 22a, 22b may be manually operated to carry out respective functions, such as those shown or listed on the display 20 in proximity to the respective soft switch. The speaker 14, microphone 16, display 20, navigation key 18 and soft keys 22a, 22b may be used and function in the usual ways in which a mobile phone typically is used, e.g. to initiate, to receive and/or to answer telephone calls, to send and to receive text messages, to connect with and carry out various functions via a network, such as the Internet or some other network, to beam information between mobile phones, etc. These are only examples of suitable uses or functions of the various components, and it will be appreciated that there may be other uses, too.

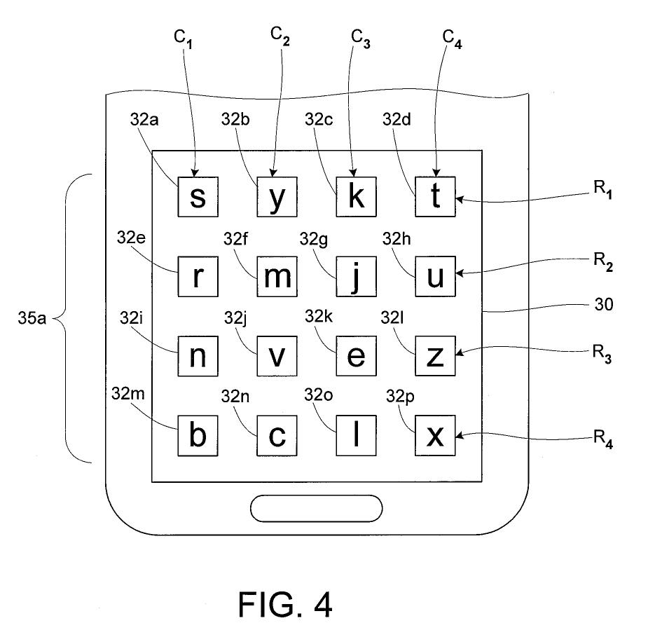

The electronic device 10 also includes a keypad area 30 comprising a plurality of keys 32 (sometimes referred to as dialing keys, input keys, etc.). The keypad area 30 may also be referred to herein as simply keypad 30. In the device 10 the keys 32 will have a character associated therewith (see, e.g., FIGS. 4-8). The characters are not limited and may include, for example, letters, numbers, symbols, combinations of two or more thereof, and the like. As shown in FIG. 1, the keys are arranged in columns (C₁-C₄) and rows (R₁-R₄). The keys 32 may be operated, e.g., manually or otherwise to provide inputs to circuitry of the mobile phone 10, for example, to dial a telephone number, to enter textual input such as to create a text message, to create an email, or to enter other text, e.g., a code, pin number, security ID, to perform some function with the device, or to carry out some other function. The keys 32 are disposed within the keypad area 30 as a keyset 35.

The keyset 35 may be characterized by the way the characters are arranged in the keyset; that is, by which keys the characters are associated with on the keypad. The keyset 35 is also referred to herein as the “character arrangement,” and the terms “character arrangement,” “keyset,” and “keyset arrangement” are used interchangeably. An example of a character arrangement may be a conventional mobile phone keypad arrangement having four rows and three columns of keys with numbers and characters associated with the keys. Another example of a character arrangement is a QWERTY keyboard arrangement. Keypad character arrangements are further discussed herein with reference to various aspects of the invention. It will be appreciated that features of the invention are not limited to keypads or keyboards on mobile electronic devices and may be employed in other types of keyboards, e.g., computer keyboards.

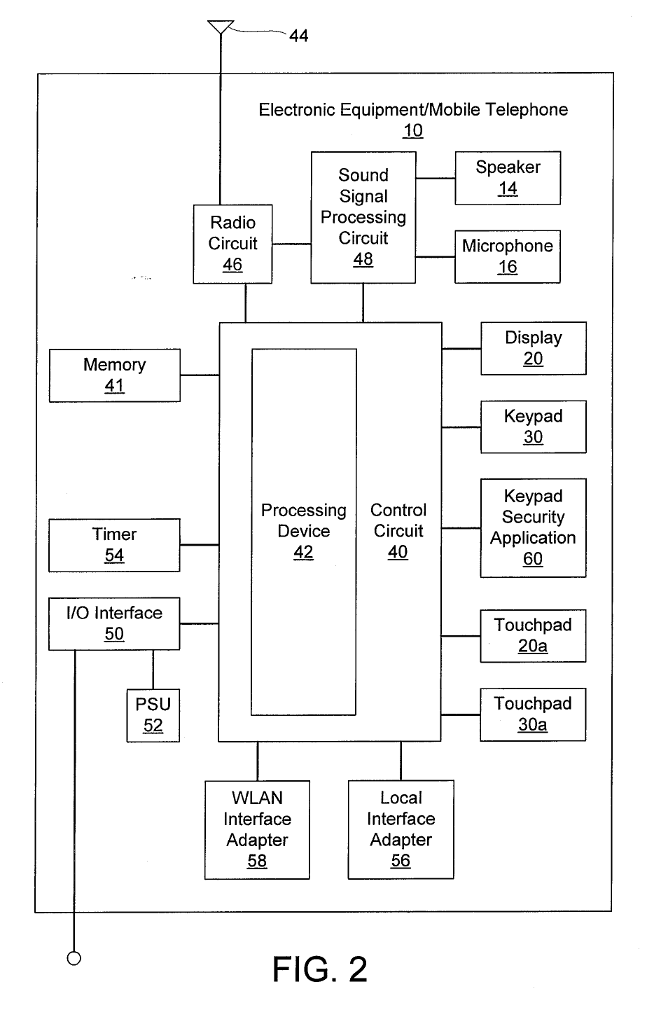

The mobile telephone 10 includes a display 20. The display 20 displays information to a user such as operating state, time, telephone numbers, contact information, various navigational menus, status of one or more functions, etc., which enable the user to utilize the various features of the mobile telephone 10. The display 20 may also be used to visually display content accessible by the mobile telephone 10. The displayed content may include E-mail messages, geographical information, journal information, audio and/or video presentations stored locally in memory 41 (FIG. 2) of the mobile telephone 10 and/or stored remotely from the mobile telephone 10 (e.g., on a remote storage device, a mail server, remote personal computer, etc.). Such presentations may be derived, for example, from multimedia files received through E-mail messages, including audio and/or video files, from a received mobile radio and/or television signal, etc. The displayed content may also be text entered into the device by the user. The audio component may be broadcast to the user with a speaker 14 of the mobile telephone 10. Alternatively, the audio component may be broadcast to the user though a headset speaker (not shown).

The device 10 optionally includes the capability of a touchpad or touch screen 20a. The touchpad 20a may form all or part of the display 20, and these are coupled to the control circuit 40 for operation as is conventional.

Various keys other than those keys illustrated in FIG. 1 may be associated with the mobile telephone 10 may include a volume key, audio mute key, an on/off power key, a web browser launch key, an E-mail application launch key, a camera key, etc. Keys or key-like functionality may also be embodied as a touch screen associated with the display 20.

The mobile telephone 10 includes conventional call circuitry that enables the mobile telephone 10 to establish a call, transmit and/or receive E-mail messages, and/or exchange signals with a called/calling device, typically another mobile telephone or landline telephone. However, the called/calling device need not be another telephone, but may be some other device such as an Internet web server, E-mail server, content providing server, etc.

Referring to FIG. 2, a functional block diagram of the mobile telephone 10 is illustrated. The mobile telephone 10 includes a primary control circuit 40 that is configured to carry out overall control of the functions and operations of the mobile telephone 10. The control circuit 40 may include a processing device 42, such as a CPU, microcontroller or microprocessor. The processing device 42 executes code stored in a memory (not shown) within the control circuit 40 and/or in a separate memory, such as memory 41, in order to carry out operation of the mobile telephone 10.

The memory 41 may be, for example, a buffer, a flash memory, a hard drive, a removable media, a volatile memory and/or a non-volatile memory.

Continuing to refer to FIGS. 1 and 2, the mobile telephone 10 includes an antenna 44 coupled to a radio circuit 46. The radio circuit 46 includes a radio frequency transmitter and receiver for transmitting and receiving signals via the antenna 44 as is conventional. The mobile telephone 10 generally utilizes the radio circuit 46 and antenna 44 for voice and/or E-mail communications over a cellular telephone network. The mobile telephone 10 further includes a sound signal processing circuit 48 for processing the audio signal transmitted by/received from the radio circuit 46. Coupled to the sound processing circuit 48 are the speaker 14 and a microphone 16 that enable a user to listen and speak via the mobile telephone 10 as is conventional. The radio circuit 46 and sound processing circuit 48 are each coupled to the control circuit 40 so as to carry out overall operation.

The mobile telephone 10 also includes the aforementioned display 20 and keypad 30 coupled to the control circuit 40. The device 10 and display 20 optionally includes the capability of a touchpad or touch screen 20a, which may be all of part of the display 20. Additionally, the device may include a touchpad or touch screen 30a, which may be part or all of the keypad area 30. The mobile telephone 10 further includes an I/O interface 50. The I/O interface 50 may be in the form of typical mobile telephone I/O interfaces, such as a multi-element connector at the base of the mobile telephone 10. As is typical, the I/O interface 50 may be used to couple the mobile telephone 10 to a battery charger to charge a power supply unit (PSU) 52 within the mobile telephone 10. In addition, or in the alternative, the I/O interface 50 may serve to connect the mobile telephone 10 to a wired personal hands-free adaptor, to a personal computer or other device via a data cable, etc. The mobile telephone 10 may also include a timer 54 for carrying out timing functions. Such functions may include timing the durations of calls and/or events, tracking elapsed times of calls and/or events, generating timestamp information, e.g., date and time stamps, etc.

The mobile telephone 10 may include various built-in accessories. For example, the device 10 may include a camera for taking digital pictures. Image files corresponding to the pictures may be stored in the memory 41. In one embodiment, the mobile telephone 10 also may include a position data receiver, such as a global positioning satellite (GPS) receiver, Galileo satellite system receiver, or the like. The mobile telephone 10 may also include an environment sensor 51 to measure conditions (e.g., temperature, barometric pressure, humidity, etc.) in which the mobile telephone is exposed.

The mobile telephone 10 may include a local wireless interface adapter 56, such as a Bluetooth adaptor to establish wireless communication with other locally positioned devices, such as the a wireless headset, another mobile telephone, a computer, etc. In addition, the mobile telephone 10 may also include a wireless local area network interface adapter 58 to establish wireless communication with other locally positioned devices, such as a wireless local area network, wireless access point, and the like. Preferably, the WLAN adapter 58 is compatible with one or more IEEE 802.11 protocols (e.g., 802.11(a), 802.11(b) and/or 802.11(g), etc.) and allows the mobile telephone 10 to acquire a unique address (e.g., IP address) on the WLAN and communicate with one or more devices on the WLAN, assuming the user has the appropriate privileges and/or has been properly authenticated.

As shown in FIG. 2, the processing device 42 is coupled to memory 41. Memory 41 stores a variety of data that is used by the processor 42 to control various applications and functions of the device 10. It will be appreciated that data can be stored in other additional memory banks (not illustrated) and that the memory banks can be of any suitable types, such as read-only memory, read-write memory, etc.

As discussed above, the device 10 includes a keypad area 30 having a plurality of keys 32 arranged in various rows (R1-R4) and columns (C1-C4). The keys 32 have a character, e.g., a letter, number, symbol, etc. associated therewith. When a user desires to input text into the electronic equipment 10, they select a particular key having the desired character they wish to input as text such as by depressing the key (in the case of a physical key) or by touching a location of a touch pad display that is displaying a virtual key. The keypad area may be provided as desired for a particular purpose or intended use. The number and primary arrangement of the keys in the keypad area may be provided as desired. The primary arrangement of the keys may refer to the arrangement of the characters on the keys 32 when the electronic device is not in security mode and/or the keypad security application is not activated. For example, the keypad area may contain a number of keys suitable for arranging the characters in a QWERTY arrangement. As another example, the keypad may contain a typical mobile phone keypad having four rows with three keys in each row. As shown in FIG. 1, the keypad area 30 has 4 rows (R1-R4) with four keys in each row such that there are four columns (C1-C4) of keys. The keypad is not so limited and may contain fewer keys (e.g., 12, 10, 5 etc.) or more keys (e.g., 20, 26, 30, etc.) as desired to suit a particular new or intended use.

In accordance with the present invention, the electronic device 10 and, particularly, keypad area 30 are provided such that the character arrangement 35 may be changed by changing the character(s) being associated with the a particular key in the keyset. That is, the keypad and keys are provided so that the arrangement of the characters on the keypad may be rearranged or reconfigured. In one embodiment, the keypad area 30 may be provided as a display 34, e.g., a touchpad display, and the keys and characters are provided as images or virtual keys on the display 34. In another embodiment, the keys may be provided as individual, physical keys. In such an embodiment, however, the physical keys would not have a set character or characters associated therewith. Rather, the individual keys would be provided such that they could have associated therewith and display different characters and so the character associated with the keys could be changed. In such an embodiment, the physical keys may be provided as individual diplays (e.g., individual LCD's buttons or keys). The individual keys may have the appropriate electrical connections to display a character or character(s) as is appropriate in the operation of the keypad security application.

The electronic device includes a keypad security application 60 (FIG. 2) to control and change the arrangement of the characters on the keys in the keypad area in response to user input. The user input will generally be in the form of a user selection of a character as input into the electronic device by physical depressing a key 32 (having an associated character) or touching an area of a touchpad display displaying a virtual key. Following selection of the desired character, the keypad security application 60 may change the arrangement of the characters on the keypad such that at least two characters are associated with different keys relative to the keys they were associated with when the user made their selection.

The keypad security application need not be run continuously during operation of the electronic device. Rather, the keypad security application may be selectively activated or run in response to a command from a user, e.g., by selecting that the application should be turned on or activated, or in response to another program or application being activated on initiated. The keypad security application 60 is coupled to the control circuit 40 for communication with the keypad 30 (FIG. 2). It will also be appreciated that the keypad security application may be stored in the memory 41.

The keypad security application 60 may provide the electronic device with another level of security when a user is inputting text into the device. By changing the arrangement of the characters associated with the keys, a person in the vicinity of the user may not be able to ascertain or know what character the user has entered as input into the device simply by observing the position of the key that the user selected.

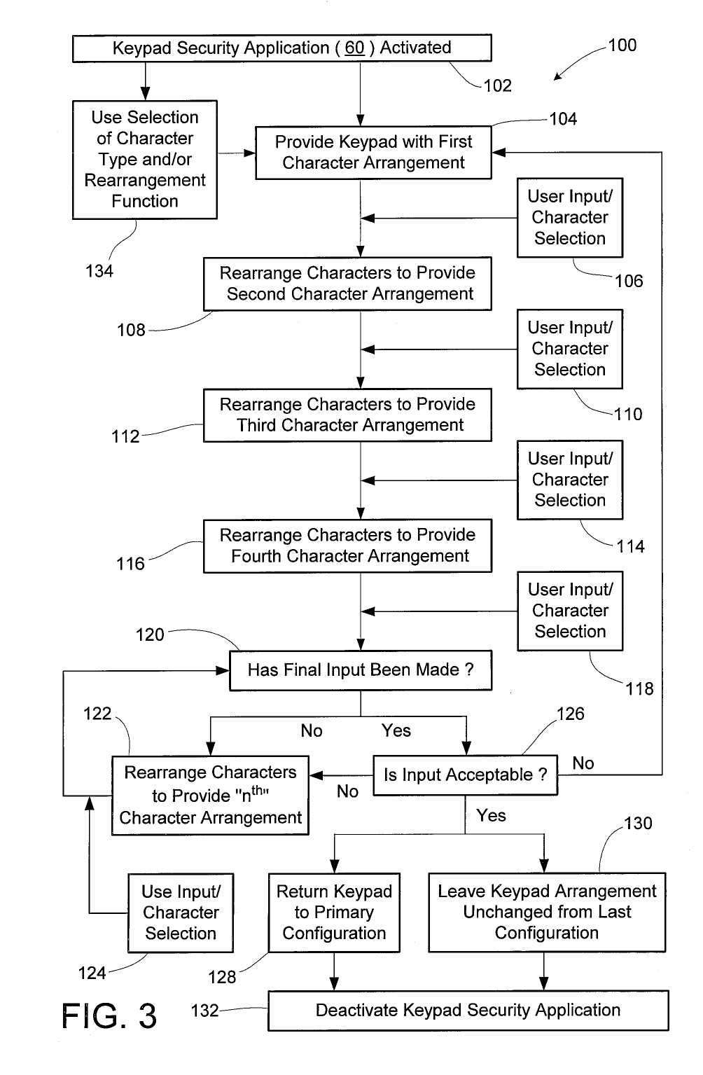

The operation of the keypad security application 60 may be further understood with reference to the program flow chart or logic diagram illustrated at 100 in FIG. 3. The flow chart 100 represents the functions that may be carried out in the operating circuitry to carry out an embodiment of the invention as an example. The functions illustrated in FIG. 3 and described herein may be provided as a computer program, for example, that is written in appropriate computer language or logic format to carry out the various steps described. A person having ordinary skill in the art would be able to write such a program to carry out the steps and functions illustrated and described herein. The various steps and functions will also be described with respect to the schematic illustrations of FIGS. 4-8.

At functional box 102, the keypad security application is activated and the keypad is provided with a first character arrangement at functional box 104, such as, for example, the character arrangement 35a shown in FIG. 4. In FIG. 4, the character arrangement 35a is provided by a particular character being associated with the respective keys 32a-32p. It will be appreciated that the keypad may have a primary character arrangement, which may refer to the arrangement of the characters prior to the keypad security application being activated. For example, a keypad having a traditional QWERTY layout may represent a primary character arrangement on a keypad area. The primary character arrangement is not particularly limited and may be any arrangement as desired employing any number of characters based on the number of keys provided in the keypad area. Upon activation of the keypad security application, the keypad security application may retain the primary character arrangement, in which case the primary character arrangement is also the first arrangement provided at functional box 104. Alternatively, the keypad security application may provide a first character arrangement that is different from the primary character arrangement.

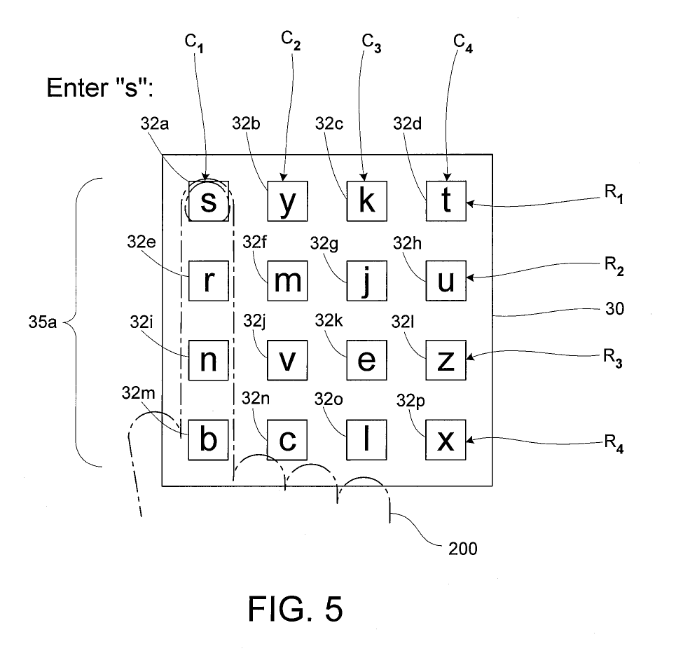

With the keys having a first character arrangement 35a, a user provides a character input (functional box 106) to the electronic device by selecting a character. FIG. 5 corresponds to the action occurring at box 106 and illustrates an example of a user 200 selecting the alpha-numeric character “s” associated with key 32a in the first character arrangement 35a.

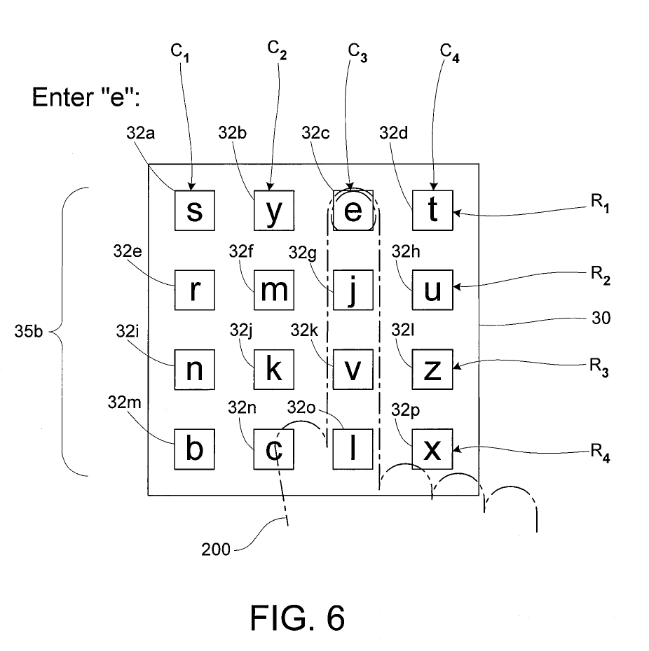

After the user inputs the desired character by selecting the appropriate key (e.g., by selecting the “s” key as shown in FIG. 5), the keypad security application rearranges the characters to provide a second character arrangement 35b (FIG. 6) at functional box 108 (FIG. 3). The characters are rearranged such that two or more characters are associated with different keys relative to the keys they were associated with in the first character arrangement 35a. For example, after the user inputs the “s” by selecting key 32a in FIG. 5, the keypad security application rearranges the characters to provide a second character arrangement 35b as shown in FIG. 6. As shown in FIG. 6, the characters “e,” “k,” and “v” have been rearranged by the keypad security application and are associated with different keys as compared to the keys they were associated with in the character arrangement 35a illustrated in FIGS. 4 and 5. In the first character arrangement 35a (FIGS. 4-5), the character “e” was associated with key 32k. In the second character arrangement 35b, the key with which the character “e” is associated has been changed to key 32c (FIG. 6). In the character arrangement 35b, the character “k” is associated with key 32, and the character “v” is associated with key 32k (as compared to character arrangement 35a in which the character “k” was associated with key 32c and the letter “v” was associated with key 32j).

Referring back to FIG. 3, after the character arrangement on the keypad has been rearranged to provide the second character arrangement (35b), the user may provide a second character input at box 110. FIG. 6, for example, illustrates a user 200 selecting the character “e” as a second character input by selecting key 32c in FIG. 6.

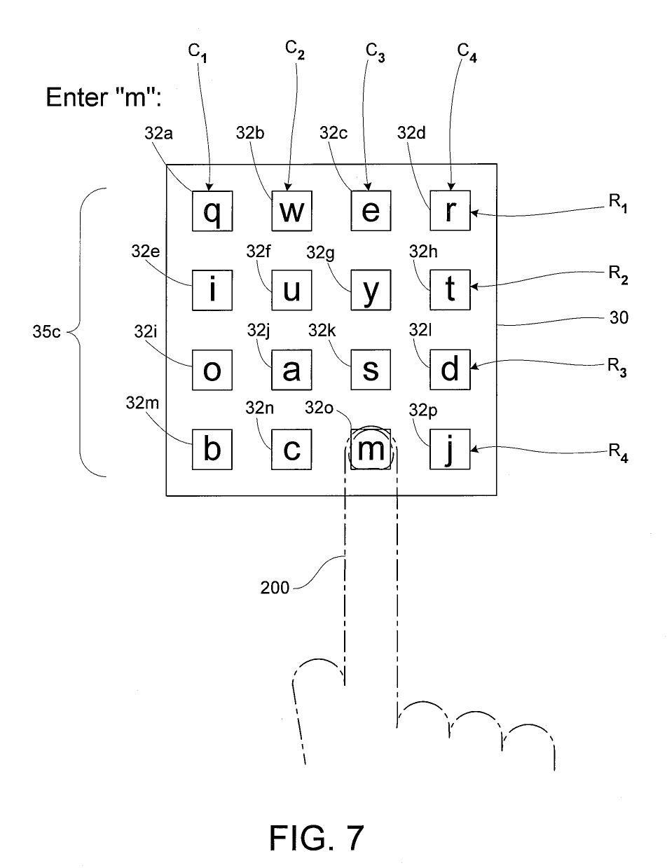

At functional box 112 in FIG. 3, following the selection and input of the second desired character, the keypad security application rearranges two or more of the characters to provide a keypad having a third character arrangement (35c in FIG. 7). For example, after the user 200 has selected and input the character “e”, the keypad security application rearranges the characters associated with two or more keys 32 to provide a third character arrangement 35c illustrated in FIG. 7. In character arrangement 35c, more than three characters have been rearranged and associated with a different key as compared to character arrangement 35b.

At box 114 in FIG. 3, the user may enter another character as input. In FIG. 7, for example, the user 200 is shown as selecting the character “m,” which is now associated with key 32o. In character arrangements 35a and 35b, the character “m” was associated with key 32f.

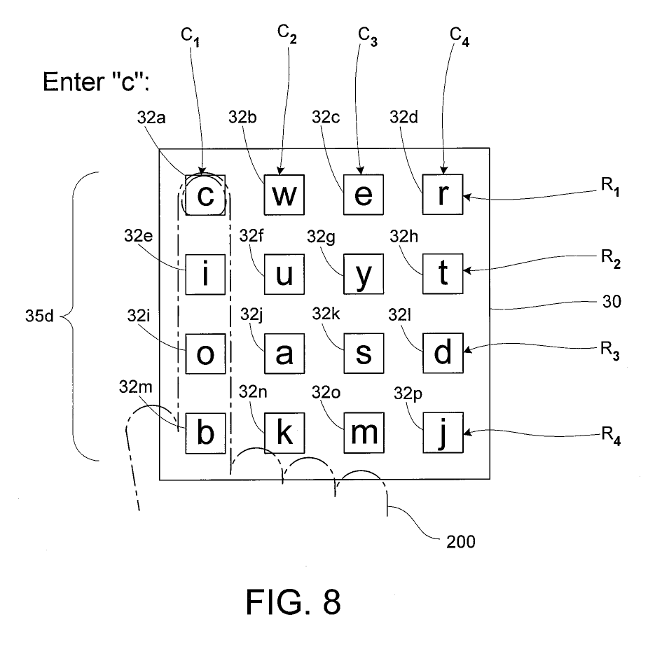

At functional box 116 in FIG. 3, following the selection and input of the third desired character, the keypad security application rearranges the characters to provide a fourth character arrangement. As shown in FIG. 8, for example, the characters have been arranged to provide a fourth character arrangement 35d in which two or more characters are now associated with different keys as compared to arrangement 35c in FIG. 7.

If desired, a user may select and input another desired character, as shown in box 118 of FIG. 3. FIG. 8 illustrates the user 200 as selecting the character “c”, which is associated with key 32a in arrangement 35d. In arrangements 35a-c, the character “c” is shown as being associated with key 32n.

At functional box 120, the keypad security application determines if the desired number of characters have been entered. If the desired number of characters has been entered, the logic flow proceeds to functional box 126. At functional box 126, the keypad security application determines if the input is acceptable. Another program running simultaneously with the keypad security application and for which the desired input is being made may communicate with the keypad security application and indicate whether the input is or is not acceptable. For example, if the input is a four character password (e.g., a pin number or code), an application that is requesting the password may recognize that the correct code was not entered and provide an indication to the keypad security application that the code was not accepted. The logic flow may then proceed to either functional box 104 or 122 and the process of entering characters as input may begin again.

If the input is acceptable, the logic flow may proceed to functional box 128 or 130. At functional box 128, the keypad security application changes the arrangement of the characters on the keypad to a desired character arrangement such as, for example, the primary or initial character arrangement (the character arrangement prior to the keypad security application being activated). Alternatively, the logic flow may proceed to functional box 130 in which the arrangement of the characters is not changed to the primary character arrangement and the character arrangement remains in the last provided arrangement. The program may then proceed to functional box 132, in which the security keypad application is deactivated. The flow to functional box 128 or 130 may be preprogrammed in the keypad security application. Alternatively, the keypad security application may be programmed to provide a prompt on display 20 and request user input or confirmation to proceed to the function illustrated in functional box 128 or 130.

In one embodiment, the desired number of character inputs may be a pre-determined number of character inputs recognized by the keypad security application or by another application operable to communicate with the keypad security application that the desired or pre-determined number of characters have been input. In another embodiment, a user may indicate that the desired number of character inputs have been made in response to a prompt or inquiry appearing on the display 20 or by selecting an “enter” or “return” key to indicate that the last desired character has been entered.

If the desired number of characters has not been entered, the program may move to functional box 122 and rearrange the characters to provide an nth character arrangement. At box 124, the user may select another character to input, and the program may proceed back to box 120 to determine if the desired number of character inputs has been reached. The process illustrated by boxes 120-126 may be repeated until the desired (or correct) textual input has been entered into the device.

The logic flow and location of functional boxes 120-130 is merely exemplary of the illustrated and described embodiment. It will be appreciated that the keypad security application may perform these steps after every input selection by the user.

The keypad security application may be activated in any suitable manner. In one embodiment, the keypad security application may be manually selected and activated by the user. In another embodiment, the keypad security application may be automatically activated such as in response to the activation of another application or program. For example, if a program is being run and requires input of a security code, the initialization or activation of the program or the program's request for private or sensitive input such as a security code or pin number may send a message to the processor to activate and run the keypad security application.

It will be appreciated that the features illustrated in FIG. 3 and FIGS. 5-8 are merely an exemplary embodiment and not intended to limit aspects of the invention. For example, the keypad security application does not have to rearrange the characters after each selection by a user of a character as input as illustrated in FIG. 3. In one embodiment, the keypad security application may rearrange the characters after each selection of a character as input. In another embodiment, the keypad security application may rearrange the characters after a preselected number of inputs. For example, the keypad security application may rearrange the characters after every other selection, after every third selection, after every fourth selection, or after every nth selection as desired for a particular purpose or intended use. In still another embodiment, the number of inputs that are required to rearrange the characters may be randomly determined during operation of the keypad security application.

The manner in which the keypad security application rearranges the characters is not limited. In one embodiment, the rearrangement may be accomplished using a random generator program and logic to randomly associate the characters with a key following the selection of a character. In another embodiment, the keypad security application may contain a plurality of pre-stored character arrangements. The keypad security application may be programmed to provide the pre-stored arrangement(s), in a particular order or may be programmed to randomly select the pre-stored arrangement(s) that will be displayed after selection of a character is input.

The rearrangement of the characters includes the rearrangement of at least two of the characters in a character arrangement. In one embodiment, fewer than all of the characters in a keyset may be rearranged following the selection of a character by a user. FIGS. 5-8 illustrate rearranging the characters in this manner. In another embodiment, all the characters in a keyset may be rearranged following the selection of a character by a user.

As shown at functional box 134 in FIG. 3, the keypad security application user may provide the user with the option of selecting one or more features for the operation of the keypad security application. For example, upon activation of the keypad security application, the program may ask the user to select the type of characters presented on the keys (e.g., numbers only, letters only, symbols only, a combination of letters, numbers, and/or symbols, etc.). As another example, the user may be asked to select a rearrangement function (e.g., association of characters with keys by a random generation character placement program, implementation of pre-stored character arrangements, or a combination of randomly generated character arrangements and pre-stored arrangements).

While the electronic device and method of securely entering a character as input into the device have been described with reference to the portable communication device 10, it will be appreciated that the device may be embodied in other various forms. Further, the device need not include all the features shown in the illustrated embodiments. For example, an electronic device in accordance with the invention need not include a display area (such as, for example, display 20) for displaying text entered into the device. For example, keypads for home security systems or garage door openers (e.g., located near outside near the garage door) often do not include a display.

Although the invention has been shown and described with reference to certain exemplary embodiments, it is understood that equivalents and modifications may occur to others skilled in the art upon reading and understanding the specification. The present invention is intended to include all such equivalents and modifications as they come within the scope of the following claims.

1. An electronic device comprising:
a keypad for entry of at least one character as input into the electronic device by a user, the keypad comprising a plurality of keys, each key having a character associated therewith, the characters being arranged in a first character arrangement; and
a keypad security application, the keypad security application changing the arrangement of the characters on the keypad to a second character arrangement in response to entry of a character as input into the electronic device by associating at least two characters with different keys relative to the keys the at least two characters were associated with in the first arrangement.

2. The electronic device of claim 1, wherein the electronic device is a portable network device.

3. The electronic equipment of claim 1, wherein the first character arrangement is a pre-stored arrangement.

4. The electronic equipment of claim 1, wherein the first character arrangement is a randomly generated arrangement of the characters.

5. The electronic equipment of claim 1, wherein the second character arrangement is a pre-stored arrangement.

6. The electronic device of claim 1, wherein the second character arrangement is a randomly generated arrangement of the characters.

7. The electronic equipment of claim 1, wherein the keypad comprises a touch sensitive display and the keys are virtual keys displayed by the touch sensitive display.

8. The electronic equipment of claim 1, wherein the keypad comprises a plurality of physical keys.

9. A method for securely inputting information into an electronic device including a keypad having a plurality of keys, each key having a character associated therewith, the characters being disposed in a primary character arrangement on the keypad, the method comprising:
providing a first character arrangement on the keypad; and
changing the arrangement of at least two characters on the keypad following a selection of a character as input to provide a second character arrangement, the character arrangement being changed by associating at least two characters with different keys relative to the keys the at least two characters were associated with in the first arrangement.

10. The method of claim 9, wherein the first character arrangement is the same as the primary character arrangement.

11. The method of claim 9, wherein providing the first character arrangement comprises providing a character arrangement that is different from the primary character arrangement.

12. The method of claim 11, wherein providing the first character arrangement comprises providing a randomly generated character arrangement.

13. The method according to claim 11, wherein providing the first character arrangement comprises providing a pre-stored character arrangement.

14. The method of claim 9, wherein changing the arrangement of the characters on the keypad following a selection of a character as input comprises randomly generating the character arrangement.

15. The method of claim 9, wherein changing the arrangement of the characters on the keypad following a selection of a character as input comprises providing a pre-stored character arrangement.

16. The method of claim 9, comprising changing the arrangement of at least two characters on the keypad in response to each selection of a character as input.

17. The method of claim 9, comprising changing the arrangement of at least two characters on the keypad after a pre-determined number of character input selections has been made.

18. The method of claim 9, comprising changing the arrangement of at least two characters until a pre-determined end input selection has been made.

19. The method of claim 18, comprising changing the character arrangement to the primary character arrangement after the entry of the pre-determined end input selection.
